(19) United States
(12) Patent Application Publication
(10) Pub. No.: US 2007/0216405 A1
(43) Pub. Date: Sep. 20, 2007

(54) Commodity Inspection System and Inspectable Textile Product

(75) Inventors: Hideo Takeuchi, Osaka (JP); Masumi Tsumuki, Osaka (JP); Kimito Igawa, Osaka (JP); Machiko Tanaka, Osaka (JP); Takaharu Ichiryu, Osaka (JP)

Correspondence Address: FISH & RICHARDSON P.C., P.O. BOX 1022, MINNEAPOLIS, MN, 55440-1022, US

(73) Assignee: TOYO BOSEKI KABUSHIKI KAISHA, Osaka (JP)

(21) Appl. No.: 10/592,135

(22) PCT Filed: Nov. 24, 2004
(86) PCT No.: PCT/JP04/17412

§ 371 Date: Sep. 8, 2006

(30) Foreign Application Priority Data
Mar. 10, 2004 (JP) 2004-067774
Aug. 3, 2004 (JP) 2004-226763
Aug. 31, 2004 (JP) 2004-252433

(51) Int. Cl. G01R 33/12

(52) U.S. Cl. 324/228; 324/200

(57) ABSTRACT

A commodity inspection system attaches a ferromagnetic body to a genuine commodity in advance and detects the magnetic characteristic of the ferromagnetic body so as to judge whether the inspection object is a genuine commodity. The system includes: an magnetization coil for applying a magnetic field changing at a predetermined frequency to a inspection object; a detection coil for detecting the change of the magnetic flux density caused by the magnetic field change; an FFT unit for acquiring a frequency spectrum corresponding to magnetic flux density change; and a judgment unit for judging whether the inspection object is a genuine commodity according to the acquired frequency spectrum. The ferromagnetic body causes a steep magnetization reversal when a magnetic field exceeding its coercive force is applied. Unlike an ordinary ferromagnetic body, in this ferromagnetic body, the frequency spectrum corresponding to the change of magnetic flux density caused by the magnetic field changing at a low frequency has a high-frequency component of large amplitude. Accordingly, it is possible to easily judge whether the inspection commodity is genuine commodity.

### BACKGROUND OF THE INVENTION

1. Field of the Invention

The present invention relates to a system for inspecting a commodity for the purpose of discovering counterfeits, illegal sale and the like of bags, briefcases, purses, clothes, etc. The present invention relates also to an inspectable textile product which can be inspected.

2. Description of the Related Art

The recent trend is more and more counterfeits and illegal sale (which is sale of genuine commodities through a different channel from an authorized channel, e.g., by a factory for consignment manufacturing but not licensed to sell) of branded products. Although customs and otherwise appropriate institutions conduct inspection to regulate this, it is in reality difficult for customs officials and the like to spot counterfeits which are increasingly sophisticated and it is virtually impossible to detect commodities for illegal sale as they are of the same quality as genuine commodities.

A commodity inspection system is known in which, in an attempt to reduce the burden of inspection, an IC chip is embedded in a genuine commodity in advance, and a reader machine reads information contained in the IC chip, which may be the manufacturer, the country of production and the like, at customs or the like, thereby making it possible for a customs official or the like to judge whether an inspection object is a commodity for illegal sale and determine that any inspection object not containing an IC chip as a counterfeit.

Patent Document 1 (JPA H08-199498) discloses an authenticity judging apparatus which applies an alternating magnetic field upon a safety protection paper of a security in which a ferromagnetic body is embedded, detects a change of a resulting magnetic flux density, acquires a frequency spectrum corresponding to the change of the magnetic flux density, and judges whether the safety protection paper is genuine based on whether the frequency spectrum agrees with a. frequency spectrum which has been prepared in advance.

Meanwhile, Patent Document 2 (JPA H03-198195) discloses a monitor system which detects a high frequency component of an output signal induced in a detection coil due to a steep magnetization reversal caused by a metallic fiber which occurs as a monitoring object, which seats the crystalline metallic fiber shaped like a circle in cross section and prepared by melt spinning of alloy containing 80 wt % of iron or more, moves passed an object detection unit in which a magnetization coil and the detection coil are incorporated.

Further, Patent Document 3 (JPA H08-221468) describes a method of pattern layout according to which a display apparatus displays a pattern piece display area, in which multiple pattern pieces are to be shown, and a marker area (i.e., an area corresponding to a fabric) so that an operator moves each pattern piece from the pattern piece display area to the marker area and attains pattern layout

### SUMMARY OF THE INVENTION

However, an IC chip is expensive and therefore will be included in the price of a commodity, and inevitably requires a complex commodity inspection system.

Accordingly, an object of the present invention is to provide a commodity inspection system which realizes easy inspection while using a relatively inexpensive material to be attached to a commodity.

Another object of the present invention is to provide a textile product which can be inspected with a commodity inspection system which realizes easy inspection owing to mounting of relatively inexpensive ferromagnetic bodies and which is easy to handle at the time of shipment, etc.

To achieve the above objects, a first aspect of a commodity inspection system according to the present invention is directed to a commodity inspection system which mounts metallic fibers to genuine commodities, detects the magnetic characteristics of the metallic fibers and judge whether an inspection object is a genuine commodity. This system comprises a magnetic field applying means which applies upon an inspection object a magnetic field changing at a predetermined frequency, a magnetic flux detecting means which detects a change of a magnetic flux density caused by a change of the magnetic field, a frequency spectrum acquiring means which acquires a frequency spectrum corresponding to the change of the magnetic flux density, and a judgment means which judges whether the inspection object is a genuine commodity based on the frequency spectrum acquired by the frequency spectrum acquiring means. The metallic fiber gives rise to a steep magnetization reversal upon application of a magnetic field which exceeds their coercive force. Further, the metallic fiber has specific shape, which gives amplitude peak values in accordance with the shape thereof to the frequency spectrum.

A second aspect of a commodity inspection system according to the present invention is directed to a commodity inspection system which requires to mount multiple metallic fibers to genuine commodities, detects the magnetic characteristics of the metallic fibers and judges whether an inspection object is a genuine commodity. The system comprises a magnetic field applying means which applies upon an inspection object a magnetic field changing at a predetermined frequency, a magnetic flux detecting means which detects a change of a magnetic flux density caused by a change of the magnetic field, a frequency spectrum acquiring means which acquires a frequency spectrum corresponding to the change of the magnetic flux density, and a judgment means which judges whether the inspection object is a genuine commodity based on the frequency spectrum acquired by the frequency spectrum acquiring means. The metallic fiber gives rise to a steep magnetization reversal upon application of a magnetic field which exceeds its coercive force. In addition, the multiple metallic fibers are disposed to intersect each other so as to give amplitude peak values to the frequency spectrum.

A textile product according to the present invention is directed to a textile product which mounts a ferromagnetic body having a lower limit weight value which can be detected with a commodity inspection system which judges whether an inspection object is a genuine commodity, which is supposed to mount a ferromagnetic body, by means of detection of the magnetic characteristics of the ferromagnetic bodies. The commodity inspection system comprises a magnetic field applying means which applies upon an inspection object a magnetic field which changes at a predetermined frequency, a magnetic flux detecting means which detects a change of a magnetic flux density caused by a change of the magnetic field, a frequency spectrum acquiring means which acquires a frequency spectrum corresponding to the change of the magnetic flux density, a judgment means which judges whether the inspection object is a genuine commodity based on the frequency spectrum acquired by the frequency spectrum acquiring means. The ferromagnetic bodies give rise to a steep magnetization reversal upon application of a magnetic field which exceeds their coercive force, and the upper limit weight value is a smaller value of the weight of a needle which can be detected with a needle inspection system which detects whether a needle is present within the inspection object. The upper value is set to 30 mg.

In the first aspect of the commodity inspection system according to the present invention, the metallic fibers which cause a steep magnetization reversal when applied with a magnetic field exceeding their coercive force are mounted to the genuine commodities in advance. The commodity inspection system, applying an alternating magnetic field upon an inspection object, acquires a frequency spectrum. Unlike not only paramagnetic bodies and diamagnetic bodies but also unlike ordinary ferromagnetic bodies which cause a relatively slow magnetization reversal, these metallic fibers show, in response to a magnetic field which changes at a low frequency, a frequency spectrum corresponding to a change of a magnetic flux density and containing a high frequency component having a large amplitude. Further, these metallic fibers have a specific shape, thereby amplitude peak values in accordance with the shape thereof are give to the frequency spectrum. This makes it easy to judge whether the inspection object is a genuine commodity.

In the second aspect of the commodity inspection system according to the present invention, The multiple ferromagnetic metallic fibers which give rise to a steep magnetization reversal upon application of a magnetic field exceeding their coercive force are attached to a genuine commodity. The commodity inspection system, applying an alternating magnetic field upon an inspection object, acquires a frequency spectrum. Unlike not only paramagnetic bodies and diamagnetic bodies but also unlike ordinary ferromagnetic bodies which cause a relatively slow magnetization reversal, the respective multiple metallic fibers show, in response to a magnetic field which changes at a low frequency, a frequency spectrum corresponding to a change of a magnetic flux density and containing a high frequency component having a large amplitude. In addition, amplitude peak values are given to the frequency spectrum since the multiple metallic fibers are disposed to intersect each other. As a result, a user of the system can confirm easily whether the inspection object is a genuine commodity.

In the the textile product according to the present invention, the ferromagnetic bodies which cause a steep magnetization reversal when applied with a magnetic field exceeding their coercive force are mounted to the genuine commodities in advance. The commodity inspection system, applying an alternating magnetic field upon an inspection object, acquires a frequency spectrum. Unlike not only paramagnetic bodies and diamagnetic bodies but also unlike ordinary ferromagnetic bodies which cause a relatively slow magnetization reversal, these ferromagnetic bodies show, in response to a magnetic field which changes at a low frequency, a frequency spectrum corresponding to a change of a magnetic flux density and containing a high frequency component having a large amplitude. This makes it easy to judge whether the inspection object is a genuine commodity. Further, since the ferromagnetic bodies mounted to the textile products are lighter than needles which are used in the event that manufacturing of the textile products involves a sewing step and the upper limit value of the weight of ferromagnetic body is set to 30 mg, the ferromagnetic bodies will not be mistaken for needles at an inspection step at the time of shipment of the textile products, which attains easy handling of the textile products.

### BRIEF DESCRIPTION OF THE DRAWINGS

FIG. 1 is a block diagram illustrating a first embodiment of the commodity inspection system according to the present invention.

FIG. 2A shows a magnetization curve measured at a room temperature on a metallic fiber which has the diameter in circular cross section of 70 μm and the length of 50 mm and which contains 93.5 wt % of Fe and 6.5 wt % of Si.

FIG. 2B shows, as a comparative example, a magnetization curve measured at a room temperature on a metallic fiber which has the diameter in circular cross section of 120 μm and the length of 50 mm and which contains 20 wt % of Fe and 80 wt % of Ni.

FIG. 3A shows frequency spectra acquired as a result of application upon the metallic fibers having the properties shown in the FIG. 2A at a room temperature of a magnetic field which has the magnetization frequency of 60 Hz, the magnetic field amplitude of 5 Oe (oersted). (The amplitude of 0 dBm corresponds to consumption of electric power of 1 mW at the impedance of 600Ω).

FIG. 3B shows frequency spectra acquired as a result of application upon the metallic fibers having the properties shown in the FIG. 2B at a room temperature of a magnetic field which has the magnetization frequency of 60 Hz, the magnetic field amplitude of 5 Oe (oersted). (The amplitude of 0 dBm corresponds to consumption of electric power of 1 mW at the impedance of 600Ω).

FIG. 4 is a block diagram illustrating an example of a needle inspection system which detects whether a needle is present within a commodity which can be inspected with the first embodiment of the commodity inspection system according to the present invention.

FIG. 5A shows examples of the shapes of ferromagnetic bodies used in a second embodiment of the commodity inspection system according to the present invention.

FIG. 5B shows examples of the shapes of ferromagnetic bodies used in a second embodiment of the commodity inspection system according to the present invention.

FIG. 5C shows examples of the shapes of ferromagnetic bodies used in a second embodiment of the commodity inspection system according to the present invention.

FIG. 5D shows examples of the shapes of ferromagnetic bodies used in a second embodiment of the commodity inspection system according to the present invention.

FIG. 5E shows examples of the shapes of ferromagnetic bodies used in a second embodiment of the commodity inspection system according to the present invention.

FIG. 5F shows examples of the shapes of ferromagnetic bodies used in a second embodiment of the commodity inspection system according to the present invention.

FIG. 5G shows examples of the shapes of ferromagnetic bodies used in a second embodiment of the commodity inspection system according to the present invention.

FIG. 5H shows examples of the shapes of ferromagnetic bodies used in a second embodiment of the commodity inspection system according to the present invention.

FIG. 6 is a block diagram illustrating an embodiment of an illegal sale prevention aid system according to the present invention.

FIG. 7 shows, in relation to the illegal sale prevention aid system shown in FIG. 6, pattern pieces of parts forming a jacket which is one example of a commodity.

FIG. 8 shows rectangular pieces corresponding to the pattern pieces shown in FIG. 7.

FIG. 9A shows a part of pattern laying out processing performed by the pattern lay out unit shown in FIG. 6.

FIG. 9B shows a part of pattern laying out processing performed by the pattern lay out unit shown in FIG. 6.

FIG. 9C shows a part of pattern laying out processing performed by the pattern lay out unit shown in FIG. 6.

FIG. 10D shows a part of pattern laying out processing performed by the pattern lay out unit shown in FIG. 6.

FIG. 10E shows a part of pattern laying out processing performed by the pattern lay out unit shown in FIG. 6.

### DETAILED DESCRIPTION OF THE PREFERRED EMBODIMENTS

Embodiments of the present invention will now be described with reference to the attached drawings.

First Embodiment of Commodity Inspection System

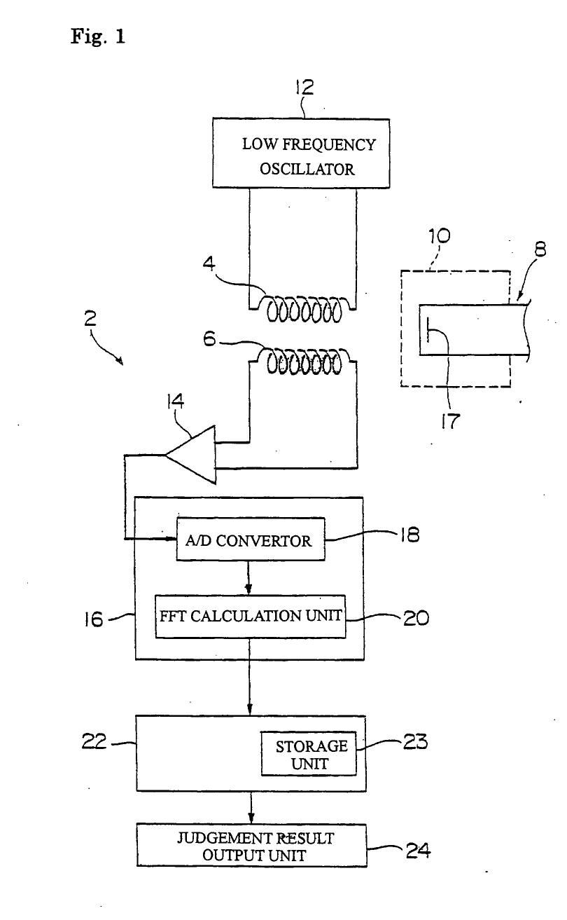

FIG. 1 shows the first embodiment of the commodity inspection system according to the present invention. This system 2 is a system which requires mounting predetermined ferromagnetic bodies to genuine commodities in advance, detects the magnetic characteristic of an inspection object and judges whether the inspection object is a genuine commodity. To be more specific, the commodity inspection system 2 comprises a magnetization coil (magnetic field generating means) 4 which generates a magnetic field and a detection coil (magnetic flux detecting means) 6 which is juxtaposed to the magnetization coil 4 and detects a magnetic flux density due to the magnetic field generated by the magnetization coil 4, and the magnetization and the detection coils 4 and 6 are disposed so as to be opposed against a region 10 which seats an inspection object 8 as a whole or a part of the inspection object 8. A core having a high magnetic permeability may be inserted into the center of the magnetization coil 4. The detection coils 4 and 6 may be disposed so as to sandwich the mount region 10. The magnetization coil 4 is connected with a low frequency oscillator 12, which applies an alternating current upon the magnetization coil 4 and develops a magnetic field H which cyclically changes.

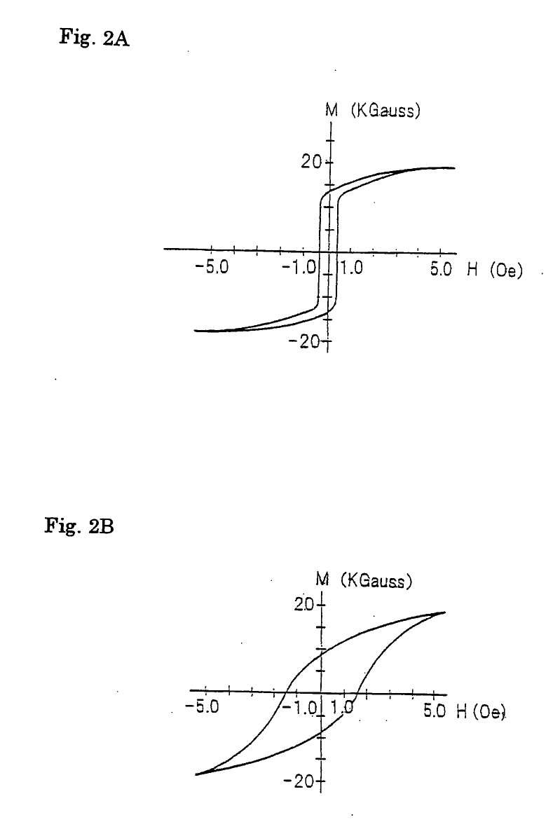

The detection coil 6 is connected with a frequency analyzer 16 through an amplifier 14. If an alternating current is applied upon the magnetization coil 4 when the region 10 seats no inspection object 8, the detection coil 6 outputs to the amplifier 14 a voltage signal (analog signal) which corresponds to a cyclically changing magnetic flux density B=μ₀H (where the symbol μ₀ denotes a magnetic permeability in vacuum). In contrast, when a ferromagnetic body 17 is attached to the inspection object 8 set in the region 10, the ferromagnetic body 17 develops magnetic polarization which is expressed in terms of magnetization M=_{χ}H (where the symbol _{χ} denotes a magnetic susceptibility), and magnetization M cyclically changes. While a curve expressing a relationship between a magnetic field H and magnetization M is generally called a “magnetization curve”, the symbol _{χ} does not denote a constant in general in the case of a ferromagnetic body (That is, _{χ} changes depending upon H.) and therefore a magnetization curve relative to a cyclically changing magnetic field H is a non-linear closed curve called a “hysteresis loop” as those shown in the sections FIGS. 2A and 2B. Hence, the detection coil 6 outputs to the amplifier 14 a voltage signal which corresponds to a cyclically changing magnetic flux density B=M+μ₀H (E-H compatible system of unit of MKSA).

In this embodiment, the ferromagnetic body 17 attached to a genuine commodity is a crystalline metallic fiber having a shape of circle in cross section and prepared by melt spinning of alloy containing 80 wt % of iron or more. This metallic fiber gives rise to a steep magnetization reversal when applied with a magnetic field exceeding its coercive force (See, JPA H03-198195 filed also by the Applicant.).

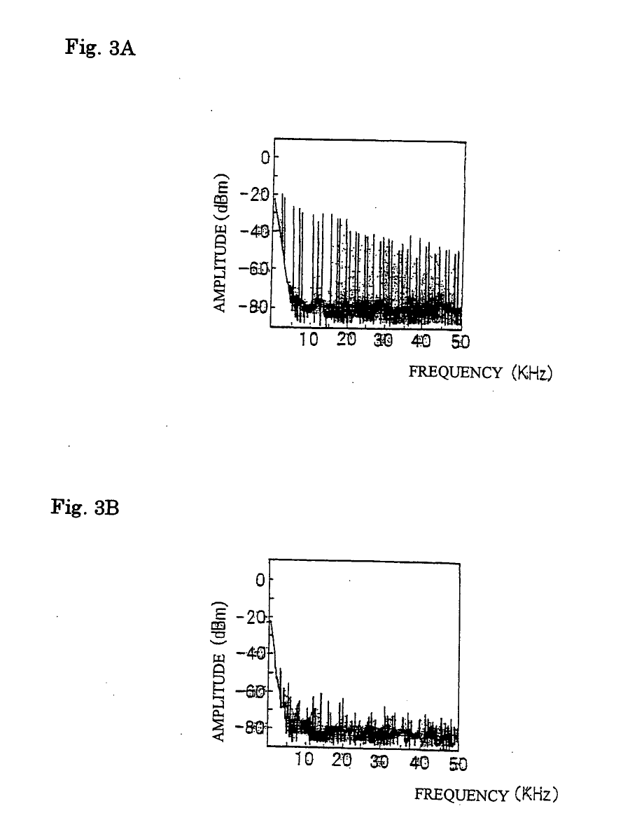

The frequency analyzer 16 comprises an A/D converter 18 which converts the analog voltage signal amplified by the amplifier 14 into a digital voltage signal and an FFT (fast Fourier transformation) calculation unit (frequency spectrum acquiring means) 20 which Fourier-transforms this digital voltage signal and obtains frequency spectrum data. Plotting frequency spectrum data along the horizontal axis denoting the frequency and the vertical axis denoting the amplitude in a graph, as those shown in the FIGS. 3A and 3B, for instance, one finds amplitude peaks at the frequency (magnetization frequency) (e.g., 60 Hz) of the low frequency oscillator 12 and at multiples of this frequency. However, since M is proportional to H in the case of paramagnetic bodies and diamagnetic bodies (as the magnetic susceptibility _{χ} is constant), no other frequency will show itself than the magnetization frequency, and further, even in the case of an ordinary ferromagnetic body which causes a relatively slow magnetization reversal as that shown in FIG. 2B for instance, the resultant frequency spectrum contains no high frequency component reaching or exceeding a certain amplitude as shown in FIG. 3B (Amplitude peaks are low at frequencies corresponding to the multiples of the magnetization frequency.). In contrast to this, the frequency spectrum of the metallic fiber described above contains a high frequency component as shown in FIG. 3A.

A judgment unit 22, which judges whether an inspection object 8 is a genuine commodity, is connected with the frequency analyzer 16. The judgment unit 22 comprises a storage unit (database) 23 which stores frequency spectrum sample data acquired through application of a magnetic field having the same magnetization frequency prior to inspection of samples of the same material and the same shape as those of the respective ferromagnetic bodies attached to genuine commodities, and comparing this sample data with frequency spectrum data output from the FFT calculation unit 20 of the frequency analyzer 16, judges whether the inspection object 8 is a genuine commodity. When the amplitude of a high frequency component in the frequency spectrum sample data stored in the storage unit 23 and that in newly acquired frequency spectrum data are approximately equal to each other for example, the judgment unit 22 determines that the inspection object 8 is a genuine commodity. A judgment result output unit 24 which notifies, using a buzzer for example, a user of the commodity inspection system 2 (a customs officer for instance) of the result of the judgment is connected with the judgment unit 22.

Alternatively, the judgment unit 22 may comprise a high-pass filter having the cut-off frequency of 10 kHz for instance and determine that the inspection object 8 is a genuine commodity when filtered frequency spectrum data contain a high frequency component whose amplitude is equal to or larger than a threshold value.

In the commodity inspection system 2 having this structure, as the low frequency oscillator 12 applies a low-frequency alternating current upon the magnetization coil 4 in a condition that the region 10 seats the entire inspection object 8 or a part of the inspection object 8, an alternating magnetic field H develops. As a result, the detection coil 6 outputs to the amplifier 14 the analog signal which corresponds to the cyclically changing magnetic flux density B. The amplifier 14 amplifies this analog signal, the A/D converter 18 then converts the analog signal into digital and the FFT calculation unit 20 thereafter Fourier-transforms the same, whereby frequency spectrum data are acquired. The judgment unit 22 compares this data with the frequency spectrum sample data which have been acquired in advance, and judges whether the inspection object 8 is a genuine commodity. Through the judgment result output unit 24, the judgment result is provided to a user of the commodity inspection system 2.

In this embodiment, the metallic fiber 17 giving rise to a steep magnetization reversal when applied with a magnetic field exceeding its coercive force is attached to a genuine commodity, and in the presence of a magnetic field changing at a low frequency unlike not only where a paramagnetic body or a diamagnetic body is used but also where an ordinary ferromagnetic body causing a relatively slow magnetization reversal is used, a frequency spectrum corresponding to a change of a magnetic flux density shows a high frequency component of a large amplitude, thereby making it easy to judge whether the inspection object 8 is a genuine commodity.

The metallic fibers 17 are preferably attached at a constant location in a constant direction to commodities, and a user is preferably notified of the locations and the directions of the metallic fibers. To attach to a jacket for instance, as shown in FIG. 1, the metallic fiber 17 is attached along a sleeve parallel to the lower sleeve edge so that the metallic fiber 17 will be oriented in a predetermined direction relative to the magnetization and the detection coils 4 and 6 as user sets the inspection object 8 in the region 10. A frequency spectrum is acquired in this condition and compared with the frequency spectra on samples oriented in this predetermined direction mentioned above stored in the storage unit 23. This is because if the direction of the metallic fibers is different, peak values of the frequency spectra will be different. However, acquisition of frequency spectrum data while directing samples in various directions prior to inspection, although increasing the volume of data to be stored in the storage unit 23, makes it possible to conduct inspection even when a user places the inspection object 8 in the region 10 without considering the direction relative to the magnetization and the detection coils 4 and 6.

Objects to which such metallic fibers can be attached include all types of commodities such as textile products, cloths, bags, wallets, belts, groceries, tapes, containers and tools. In the case of textile products in particular, with an extremely small amount of such metallic fibers sewn in the textile products, the textile products themselves are equipped with a counterfeit prevention function, which is effective in making it easier to prevent counterfeiting than where such metallic fibers are attached to indication labels such as quality labels and price tags. Being flexible, the metallic fibers will never impair the functions which the textile products are supposed to exhibit or the hand feeling of the textile products. In the event that filaments are used as the metallic fibers, the filaments may be monofilaments or multifilaments. Filaments can replace machine sewing threads in bags, wallets, belts, groceries and the like and are effective in reinforcement.

In requesting for contract manufacturing of commodities, to prevent a contract manufacturer from unduly modifying the direction of attaching the metallic fibers to commodities, the metallic fibers may be sewn in sheet-like strips of cloth used as indication labels and attached to the commodities at a fixed location in a fixed direction and provided as such to the contract manufacturer.

Although varying depending upon the location of sewing, the fiber diameter of the metallic fibers to be sewn in textile products is preferably 200 μm or smaller, and more preferably 100 μm or smaller. The diameter exceeding 200 μm will result in stiffness which will change the hand feeling and the hand feeling will become a little hard. The diameter of 1 μm or smaller is too small and difficult to handle, and therefore, should preferably be larger than 1 μm. While the fiber length of the metallic fibers is different depending upon the location of sewing, 40 mm or longer, or more preferably, about 50 mm would be sufficient. However, the metallic fibers can be used as filaments as well. In that instance, to the extent not affecting the hand feeling, the metallic fibers may be used even as multifilaments.

The ferromagnetic bodies described above which cause a steep magnetization reversal when applied with a magnetic field exceeding their coercive force may be, instead of the metallic fibers described above, amorphous fibers (amorphous metallic fibers) exhibiting a rectangular hysteresis characteristic.

By the way, a commodity now mounting the ferromagnetic body, which causes a steep magnetization reversal when applied with a magnetic field exceeding its coercive force, is inspected before shipment using a needle inspection apparatus (needle inspection system) to see if a needle (which may be a hand sewing needle, a machine sewing needle, a marking pin or the like and herein called a “remaining needle”) which was used during sewing still remains (needle inspection step). The needle inspection system aims at detecting a needle having a predetermined weight or more and made of steel (Fe—C alloy containing iron and 2% or less of carbon, and if necessary, a third element). As for the size of the ferromagnetic bodies described above attached to the commodities, the upper limit value is a smaller value than a needle which is used during sewing of the commodities and can be detected with the needle inspection system, which ensures that the ferromagnetic bodies will not react to the needle inspection system during needle inspection of the commodities using the needle inspection system (In short, at the needle inspection step, the ferromagnetic bodies will not be mistaken for needles.). On the contrary, if the ferromagnetic body is too small, the ferromagnetic body will not be responsive to the commodity inspection system 2, and therefore, a value which the commodity inspection system 2 can detect is set as the lower limit value of the weight of the ferromagnetic body.

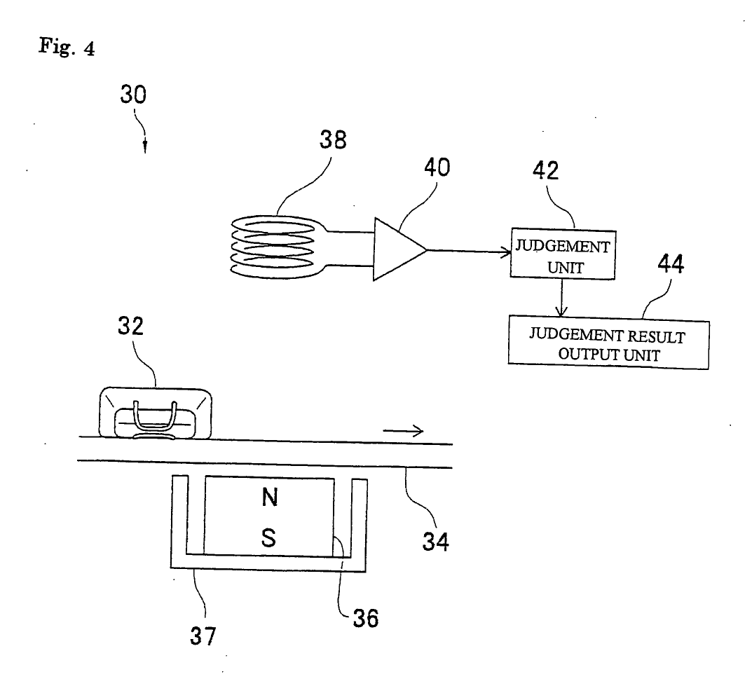

FIG. 4 shows an example of the needle inspection system. The needle inspection system 30 comprises a conveyer belt 34 which transports a needle inspection object 32 (which is a bag in the illustrated example) and a permanent magnet 36 which is opposed against the conveyer belt 34. The. permanent magnet 36 is magnetized in a direction orthogonal to the conveyer belt 34 (i.e., the top/bottom direction in FIG. 4) such that its side closer to the conveyer belt 34 will become the north pole or the south pole (the north pole in FIG. 4). A magnetic shield 37 having a high magnetic permeability surrounds the permanent magnet 36 except for the north pole so that a direct current magnetic field having a predetermined magnetic field intensity will develop in a space on the north pole side of the permanent magnet 36. The means which develops a direct current magnetic field may be an electromagnet instead of the permanent magnet 36. There is a detection coil 38 inside the direct current magnetic field developing in the space on the north pole side of the permanent magnet 36 so that magnetic fluxes of the direct current magnetic field created by the permanent magnet 36 interlink with the detection coil. The detection coil 38 is connected with a judgment unit 42 via an amplifier 40. The detection coil 38 outputs to the amplifier 40 a voltage signal (analog signal) corresponding to the number of magnetic fluxes created by the permanent magnet 36 and interlinking with the detection coil. If there is a remaining needle inside the needle inspection object 32, as the conveyer belt 34 conveys the needle inspection object 32 through the opposed region of the permanent magnet 36 and the detection coil 38, a distribution of the magnetic fluxes in the direct current magnetic field created by the permanent magnet 36 changes due to the remaining needle left inside the moving needle inspection object 32 (In other words, the number of magnetic fluxes interlinking with the detection coil 38 changes.). The amplifier 40 amplifies the voltage signal detected by the detection coil 38, and outputs the same to the judgment unit 42. The judgment unit 42 is disposed for judging whether there is a remaining needle left inside the needle inspection object 32, and judges that the needle inspection object 32 contains a remaining needle when the peak value of the voltage signal amplified by the amplifier 40 is equal to or larger than a predetermined threshold value. A judgment result output unit 44, which notifies, using a buzzer for example, a user of the needle inspection system 30 (e.g., a shipment manager) of the judgment result is connected with the judgment unit 42.

While manufacturing of commodities generally involves a sewing step, needles for sewing include hand sewing needles (cotton sewing needles, “gasu” sewing needles, pongee fabric sewing needles, silk sewing needles, sewing needles with oval eyes), machine sewing needles, marking pins, etc. As for the respective hand sewing needles, the smallest includes a cotton sewing needle weighing about 170 mg (No. 5 according to the JIS Standard), a gasu needle weighing about 170 mg (No. 9 according to the JIS Standard), a pongee fabric sewing needle weighing about 98 mg (No. 5 according to the JIS Standard), a silk sewing needle weighing about 39 mg (No. 13 according to the JIS Standard) and a sewing needle with an oval eye weighing about 45 mg (No. 9 according to the JIS Standard). Marker pins are about the same in size as hand sewing needles. Machine sewing needles are larger than hand sewing needles, and a broken piece of a broken machine sewing needle is usually larger than the smallest hand sewing needles. In light of this, the upper limit value of the weight of the ferromagnetic body attached to a commodity is set to about 30 mg, thereby reducing the peak value of the voltage signal amplified by the amplifier 40 in relation to the ferromagnetic body below the predetermined threshold value and preventing the judgment unit 42 of the needle inspection system 30 from erroneously confirming the existence of a needle in the needle inspection object 32. In the event that such a metallic fiber as that described above is used as the ferromagnetic body, iron accounts for 80% or more in weight. When iron accounts for about 100% in weight, the weight of iron is lighter than 30 mg, which makes it possible to prevent the ferromagnetic body from getting mistaken for a needle without fail. In the case of the metallic fiber above in which iron accounts for even less in weight, while it is possible to prevent the ferromagnetic body from getting mistaken for a needle when the weight of the metallic fiber is about 30 mg since the weight of iron is therefore lighter than 30 mg, even if the weight is increased over 30 mg to a certain extent (up to about 35 through 40 mg for instance), since the weight of iron is at most about 30 mg, it is still possible to prevent the ferromagnetic body from getting mistaken for a needle.

Second Embodiment of Commodity Inspection System

The commodity inspection system in this embodiment, although having substantially the same structure as that of the commodity inspection system 2 shown in FIG. 1, aims at making it possible to judge the attributes (the manufacturer and the country of production for instance) of an inspection object and making it possible for a user of the system to judge whether the object has put into distribution through an authorized channel.

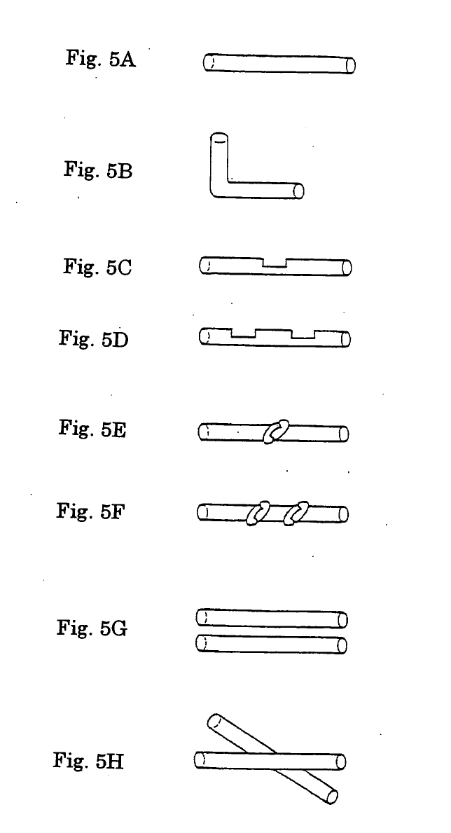

To be more specific, as the ferromagnetic bodies, crystalline metallic fibers shaped like a circle in cross section and prepared by melt spinning of alloy containing 80 wt % of iron or more are attached in advance to multiple same commodities (which may be textile products for instance). In the event that the attributes of commodities have different attributes (which may for example be the manufacturer), the ferromagnetic bodies having a different shape (although the material is same) are attached to the commodities. With reference to FIGS. 5A through 5H, depending upon the manufacturer, each ferromagnetic body is attached to each commodity, in the form of one metallic fiber which is linearly shaped or L-shaped a s shown in FIGS. 5A and 5B, in the form of a metallic fiber which is notched at one or more locations as shown in FIGS. 5C and 5D, in the form of a metallic fiber which is knotted at one or more locations as shown in FIGS. 5E and 5F, or in the form of two metallic fibers which are set linearly parallel to each other or intersecting each other as shown in FIGS. 5G and 5H. Although staples are preferably used as the metallic fibers, filaments may be used instead, in which case the filaments may be monofilaments or multifilaments. Frequency spectrum samples are acquired on the samples of the same material and the same shape as those of such ferromagnetic bodies, and stored in the storage unit 23 of the judgment unit 22 together with the attributes of the commodities. While amplitude peaks appear at the magnetization frequency and at multiples of this frequency in the frequency spectra, the peak values are different in accordance with the shapes of the metallic fibers. During inspection, in a similar manner to that described in relation to the first embodiment, a frequency spectrum is obtained on the inspection object 8, and the judgment unit 22 judges, based on this spectrum, the attributes of the inspection object 8 while referring to the storage unit 23 which stores a relationship between the frequency spectra acquired in advance on the samples and the attributes of the commodities mounting the ferromagnetic bodies of the same material and the same shape as those of the samples. The judgment result output unit 24 may for example be a monitor which displays the attributes of the commodities such as the manufacturer.

As described above, since it is possible to judge the attributes of inspection objects in this embodiment, a user can confirm who manufactured the inspection objects for instance based on the judgment result, and can consequently confirm whether the inspection objects are commodities for illegal sale. In addition, since the ferromagnetic bodies are of the same material (rather than attaching ferromagnetic bodies of different materials to the commodities), it is possible to reduce the cost of manufacturing the ferromagnetic bodies attached to the commodities.

Unlike in the first embodiment, it is not necessary for the ferromagnetic bodies to give rise to a steep magnetization reversal when applied with a magnetic field exceeding their coercive force in this embodiment, but rather ordinary ferromagnetic bodies causing a relatively slow magnetization reversal can also be used.

As in the first embodiment, in an effort to decrease the volume of frequency spectrum sample data to store in the storage unit 23, the ferromagnetic bodies are preferably attached at a constant location in a constant direction to the commodities and a user is preferably notified of the locations and the directions of the ferromagnetic bodies in this embodiment as well.

As in the first embodiment, the upper limit value of the weight of the ferromagnetic bodies attached to the commodities is such a value which a needle inspection system (which may for instance be the needle inspection system 30 shown in FIG. 4) can not detect in this embodiment as well to thereby ensure that during needle inspection of the commodities using the needle inspection system, the ferromagnetic bodies will not react to the needle inspection system. On the other hand, if the ferromagnetic bodies attached to the commodities are too small, the ferromagnetic bodies will not react to the commodity inspection system of this embodiment, and hence, the lower limit value of the weight of the ferromagnetic bodies is such a value which the commodity inspection system can detect.

Illegal Sale Prevention Aid System

One example of the illegal sale prevention aid system according to one embodiment of the present invention will now be described. This system aims at aiding, in relation to commodities which can be inspected with a commodity inspection system, a consigner of contract manufacturing prevent illegal sale by a contract manufacturer after requesting for contract manufacturing and providing the manufacturer with fabrics for commodities and ferromagnetic bodies.

The present invention assumes that a contract manufacturer is entrusted to manufacture commodities (genuine commodities) to which metallic fibers are attached. In this instance, the consigner provides the contract manufacturer with materials (fabrics), metallic fibers, and information regarding drawings of the commodities, the length of the metallic fiber per commodity and the like, and receives from the contract manufacturer the requested number of the commodities. However, there is a concern that the contract manufacturer could do tailoring so as to manufacture more commodities than the requested volume, illicitly change the length of the metallic fiber per commodity, leaving extras of the metallic fibers and unduly obtaining the metallic fibers, attach the extra metallic fibers to other commodities than those delivered to the consigner and commit illegal sale. As the commodities for illegal sale have the same quality as the genuine commodities and mount the metallic fibers, it is not possible to identify them with the first embodiment of the commodity inspection system described earlier. Noting this, the illegal sale prevention aid system according to the present invention calculates the number of the commodities which can be made out of the fabrics provided to the contract manufacturer from information regarding the fabrics and the commodities to be manufactured, and provides the consigner with information regarding the calculated number. If the consigner tells the contract manufacturer the information regarding the requested number of the commodities to be manufactured, it will become difficult for the contract manufacturer to gain extras of the fabrics, and even when succeeding in obtaining extras of the metallic fibers, it will still be difficult to manufacture more commodities than the requested amount.

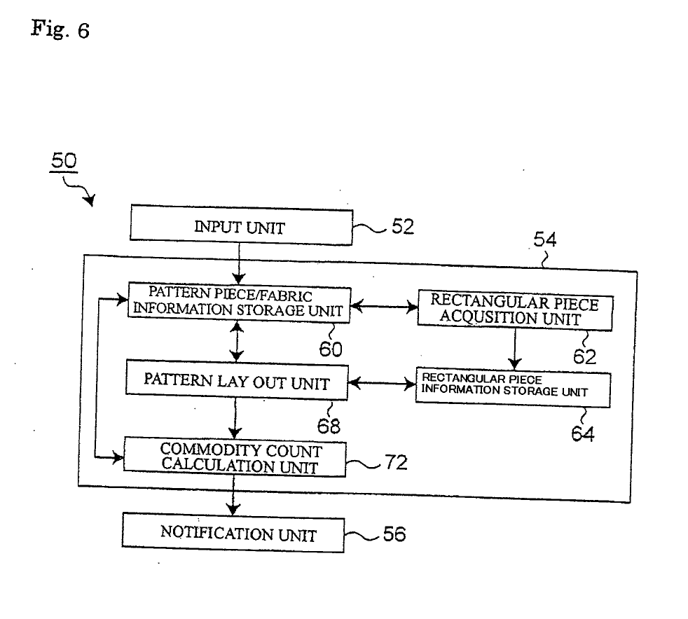

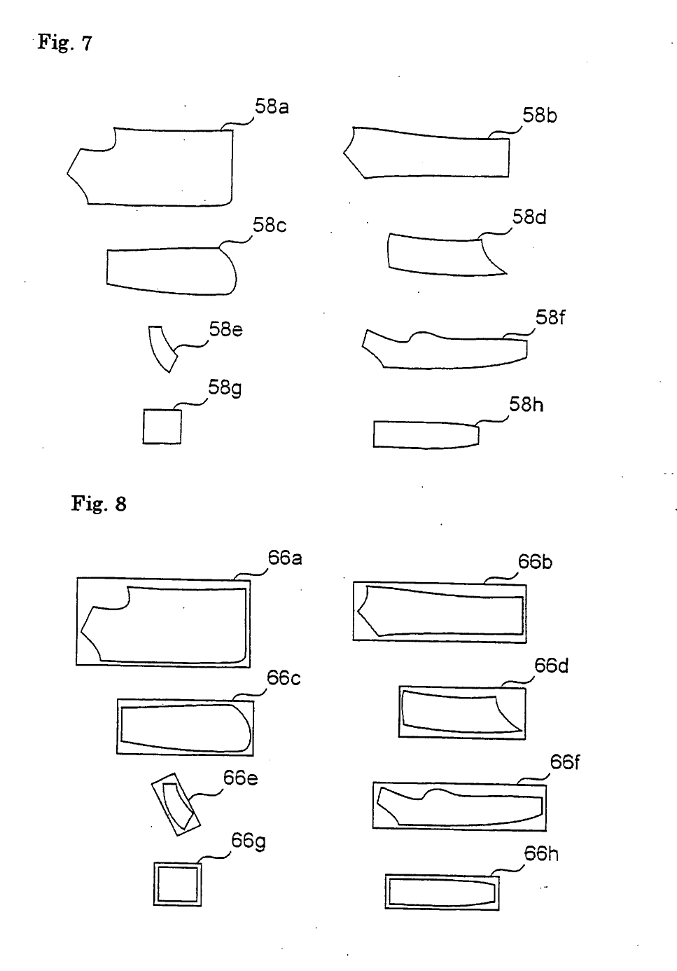

FIG. 6 shows an embodiment of the illegal sale prevention aid system according to the present invention which aims at estimating the number of commodities which can be manufactured. This system 50 comprises an input unit 52 for inputting pattern piece information regarding the sizes and the shapes of pattern pieces (paper patterns) of parts which form commodities and fabric information regarding the size and the shape of a fabric (roll of cloth) which is for manufacturing the commodities and is substantially a long roll, a computer 54 which executes predetermined calculation based on the information input at the input unit 52, and a notification unit 56 such as a speaker and a monitor which notifies an operator of the system 50 (the manufacturer or a person relevant to manufacturing) of the calculation result. FIG. 7 shows an example of the parts of a commodity. This commodity is a jacket which is formed by a front bodice 58a, a back bodice 58b, a top sleeve 58c, an under sleeve 58d, a piece 58e for sewing a collar in the back part, a facing 58f, a pocket 58g, a side pocket 58h, etc.

The input unit 52 may be an apparatus (which may be a key board, a mouse, or a graphic interface) on which an operator manually enters the pattern piece information and the fabric information, or alternatively, an apparatus which images models for the pattern pieces of the parts, which an operator have prepared in advance in relation to the pattern piece information, and acquires the pattern piece information based on the resulting imaging data. The pattern piece information and the fabric information entered via the input unit 52 are stored in a storage unit 60. The pattern piece information stored in the pattern piece/fabric information storage unit 60 expresses the outer shape of a pattern piece in a plane coordinates system for instance.

The computer 54 is for estimating the number of the commodities which can be manufactured from the fabrics based on the pattern piece information and the fabric information. To be more specific, the computer 54 comprises a rectangular piece acquisition unit 62 which acquires rectangular piece information regarding the sizes and the shapes of rectangular pieces of rectangles which encompass and substantially express the respective pattern pieces based on the pattern piece information input through the input unit 52 and stored in the pattern piece/fabric information storage unit 60. A storage unit 64 stores the rectangular piece information. Describing in detail, the rectangular piece acquisition unit 62 calculates a rectangular piece which is occupied as much as possible by a pattern piece, based on the pattern piece information stored in the pattern piece/fabric information storage unit 60. FIG. 8 shows rectangular pieces 66a through 66h for the components 58a through 58h shown in FIG. 7, acquired by the rectangular piece acquisition unit 62. As one example of a method of calculating the rectangular pieces, from the information regarding each pattern piece stored in the pattern piece/fabric information storage unit 60, rectangular piece candidates are determined which encompass the pattern piece and have long sides or short sides along a predetermined direction and a direction perpendicular to the predetermined direction. The direction is modified, thereby identifying rectangular piece candidates. From among these rectangular piece candidates thus determined, one having the smallest area size is chosen as a rectangular piece. Although neither one of the long and the short sides of the rectangular piece contains any point which is on the outer shape of the pattern piece as shown in FIG. 8, these sides may contain such points. Further, in the event that the pattern piece has a linear outer shape portion, the outer shape of the rectangular piece may contain this portion.

Referring back to FIG. 6, the computer 54 further comprises a pattern lay out unit 68 which identifies a fabric piece in which all rectangular pieces corresponding to one commodity can be laid out (marking), based on the length along the width direction in the fabric information stored in the pattern piece/fabric information storage unit 60 and based on the rectangular piece information acquired by the rectangular piece acquisition unit 62 and stored in the rectangular piece information storage unit 64.

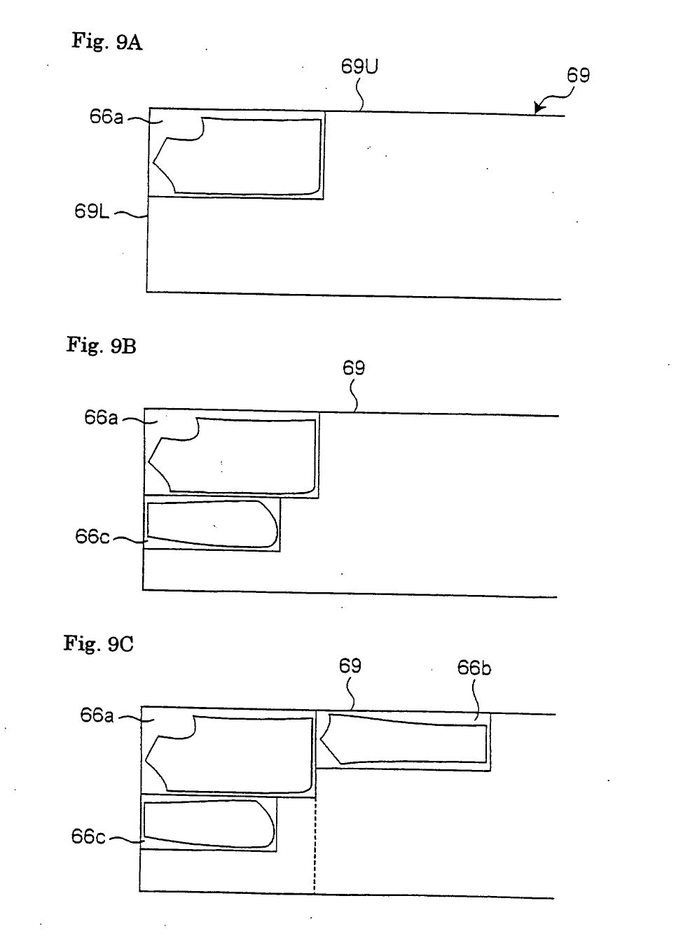

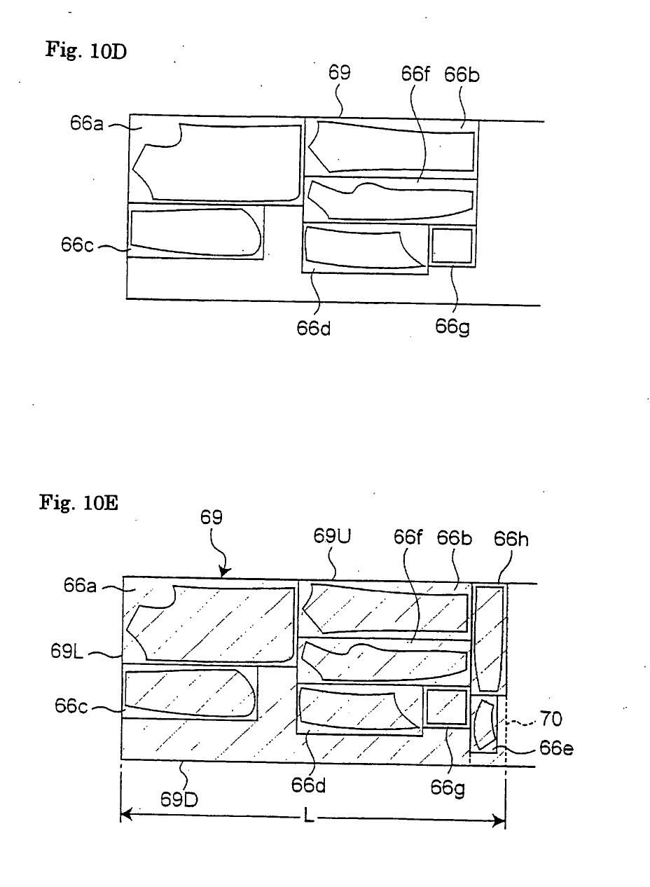

Referring to FIGS. 9A through 9C, 10D and 10E, the pattern lay out unit 68 determines a fabric piece in the manner described below for example. In the following, the right/left direction in FIGS. 9A through 9C, 10D and 10E is the longitudinal direction of a fabric 69 while the top/bottom direction in is the width direction.

First, the largest one of the rectangular pieces (i.e., the rectangular piece 66a corresponding to the front bodice 58a (FIG. 7) in the illustrated example, which will be hereinafter referred to as “the maximum rectangular piece”) is arranged on the upper left corner for instance [FIG. 9A] so that its one side comes over the short side 69L (which is along the width direction) and the long side 69U (which is along the longitudinal direction) of the fabric 69. Although any one of the short and the long sides of the maximum rectangular piece 66a may be aligned to the short side 69L at the far left of the fabric, such an arrangement should be chosen which minimizes the area below the maximum rectangular piece 66a and the length of the maximum rectangular piece 66a along the longitudinal direction. Next, if there is one or more rectangular pieces which can fit in the area below the maximum rectangular piece 66a, such a rectangular piece is placed in this area [FIG. 9B] (In the illustrated example, there is only one such rectangular piece which is the rectangular piece 66c. Although the rectangular piece 66c is located so that its top side matches with the bottom side of the maximum rectangular piece 66a in the illustrated example, rectangular pieces, one at the top and the other at the bottom, may be spaced apart from each other.). However, the right side of the far-right rectangular piece to place within this area must be located toward the left relative to the right side of the maximum rectangular piece 66a. Alternatively, the right side of the far-right rectangular piece to place within the area, to the extent staying within a predetermined length, may stick out toward the right beyond the right side of the maximum rectangular piece 66a.

Following this, from among the remaining rectangular pieces, the largest one (which is the rectangular piece 66b in the illustrated example) is positioned on the upper left corner for instance [FIG. 9C] so that its one side comes over the right side of the maximum rectangular piece 66a (or the right side of the rectangular piece below the maximum rectangular piece 66a or a line extending from this right side). If there is one or more rectangular pieces which can fit in the area below the rectangular piece 66b, such a rectangular piece is placed in this area (i.e., the rectangular pieces 66d, 66f and 66g in the illustrated example) [FIG. 10D]. The lay out processing above is repeated further on the remaining rectangular pieces (which are the rectangular pieces 66e and 66h in the illustrated example), thus completing laying out of all rectangular pieces 66a through 66h on the fabric 69 [FIG. 10E]. The pattern lay out unit 68 obtains, as a fabric piece, a region [the shaded section in FIG. 10E] enclosed by a line 70 consisting of the right side of the right-most one among these rectangular pieces and an extended line of this right side, and the left side 69L, the top side 69U and the bottom side 69D of the fabric.

As shown in FIG. 6, the computer 54 further comprises a calculation unit 72 which calculates the number of the commodities which can be manufactured from the fabric, and the pattern lay out unit 68 sends to the commodity count calculation unit 72 information regarding the length L [FIG. 10E] of the fabric piece along the longitudinal direction (The pattern lay out unit 68 thus functions as a fabric piece length calculation unit which calculates the length L of the fabric piece 69 along the longitudinal direction.). Based on the length L of the fabric piece along the longitudinal direction and based on the length of the fabric along the longitudinal direction supplied to the manufacturer from among the fabric information stored in the pattern piece/fabric information storage unit 60, the commodity count calculation unit 72 calculates the number of the commodities. Information related to the number calculated by the commodity count calculation unit 72 (including the information representing the number itself) is provided as notification via the notification unit 56.

In the illegal sale prevention aid system 50 having such a structure, upon entry of the pattern piece information regarding the sizes and the shapes of pattern pieces of parts which form commodities and the fabric information regarding the size and the shape of a fabric for manufacturing of the commodities which is approximately in the form of a long roll through the input unit 52, the pattern piece information and the fabric information are stored in the pattern piece/fabric information storage unit 60 of the computer 54. Next, the rectangular piece acquisition unit 62 of the computer 54 acquires rectangular pieces containing pattern pieces based on the pattern piece information stored in the pattern piece/fabric information storage unit 60, and makes the rectangular piece information storage unit 64 store the rectangular piece information regarding the sizes and the shapes of the rectangular pieces. Following this, the pattern lay out unit 68 of the computer 54, based on the length along the width direction included in the fabric information stored in the pattern piece/fabric information storage unit 60 and based on the rectangular piece information stored in the rectangular piece information storage unit 64, identifies the fabric piece 49 in which all rectangular pieces corresponding to one commodity can be laid out (marking) in the manner described above and outputs the length L of the fabric piece along the longitudinal direction to the commodity count calculation unit 72. The commodity count calculation unit 72 then calculates the number of the commodities based on this length and the length of the fabric along the longitudinal direction supplied to the manufacturer which is included in the fabric information stored in the pattern piece/fabric information storage unit 60. At last, the notification unit 56 notifies an operator of information regarding the number calculated by the commodity count calculation unit 72.

Based on the number learned from the notification unit 56, the consigner provides the manufacturer with the metallic fibers corresponding to the notified number together with the information regarding the number of the commodities which the consigner request to manufacture. In this instance, since it is difficult for the manufacturer to manufacture the commodities using extra fabrics, and hence, manufacture the commodities for illegal sale. Meanwhile, in the case of laying out pattern pieces within a fabric on a display screen in accordance with instructions from an operator as that described in Patent Document 3, although such laying out is closer to actual laying out, the operator is still heavily burdened. On the contrary, where this embodiment of the illegal sale prevention aid system is used, it is easy for the consigner to learn about the number of the commodities which can be manufactured and the amount of the metallic fibers to be supplied to the manufacturer.

There still is a possibility that the manufacturer will leave sufficient extras of fabrics to manufacture an excessive number of the commodities, illicitly change the length of the metallic fiber per commodity and leave extra metallic fibers. In this instance, the commodities obtained from the extras of fabrics and the extra metallic fibers, mounting the metallic fibers, could be overlooked by the commodity inspection system 2 and illegally sold. To handle this, it is preferable to supply the manufacturer the metallic fibers of a predetermined length as they are already sewn in sheet-like strips of cloth used as indication labels or the like so that it will be impossible for the manufacturer to change the amount of the metallic fiber per commodity and leave extra metallic fibers. Since such sheet-like strips of cloth are attached to commodities at a fixed location in a fixed direction, this is effective also in preventing the manufacturer from unduly changing the direction of attaching the metallic fibers to the commodities.

While the foregoing has described the lay out processing using the pattern lay out unit 68 in relation to a single-piece item which is a jacket, a commodity may be formed by two or more parts (e.g., a suit consisting of a jacket and trousers).

Although the lay out processing using the pattern lay out unit 68 does not consider printings, stripes or the like of a fabric in the embodiment above, there may be a situation that a manufacturer must consider these in actually laying out for a commodity, in the case of cloths particularly, so as not to impair the value of the product. Hence, the lay out processing using the pattern lay out unit 68 may be conducted with a restriction upon the directions of rectangular pieces, neighboring rectangular pieces or the like (e.g., a requirement that the rectangular piece 66a corresponding to the front bodice 58a and the rectangular piece 66b corresponding to the back bodice 58b must be next to each other).

Further, although the rectangular piece acquisition unit 62 automatically executes the processing for obtaining rectangular pieces from a pattern piece in this embodiment, instead of this, the illegal sale prevention aid system may comprise a display unit and an input unit (Alternatively, the input unit 52 may serve this function as well.), the display unit may display a similar figure to a pattern piece (which may be a similar figure of the same size as the pattern piece), an operator may designate on a display screen a rectangular piece surrounding the similar figure to the pattern piece via the input unit, and a rectangular piece may be obtained in response to this designation.

While the foregoing has described the present invention in relation to specific embodiments, the present invention is not limited to these but may rather be modified in various ways. For instance, although the embodiments above use the detection coil 6 as the magnetic flux detecting means which detects a change of a magnetic flux density in the commodity inspection system 2, a Hall element, an MR (magneto-resistive) element or the like may used instead.

With respect to the needle inspection system 30, where in the needle inspection object 32 a needle is left is unknown, and therefore, (particularly when the needle inspection object 32 is relatively thick) different relative locations (including the locations of the centers of gravity and the directions) of a remaining needle and the conveyer belt 34 make the detection coil 38 output the voltage signal having a different peak value. In light of this, various relative locations of the smallest ones of needles used at a sewing step (for instance, one silk sewing needle weighing approximately 39 mg (No. 13 according to the JIS Standard)) to the conveyer belt 34 may be set, the needle inspection system 30 may execute needle inspection and identify the various peak values of the voltage signal which is output from the detection coil 38, and the smallest peak among them may be used as a threshold value which serves as a judgment criterion for the judgment unit 22.

In the event that ferromagnetic bodies contain metal, the needle inspection system is not limited to the magnetic induction type but may be of the electromagnetic induction type (so-called metal detector).

Further, while the system 2 described as the embodiments above is suitable as a commodity inspection system which is for detecting a counterfeit of a commodity which is protected against illegal sale owing to the illegal sale prevention aid system according to the present invention, a different structure may be used as long as it requires attaching ferromagnetic bodies to genuine commodities and judges whether an inspection object is a genuine commodity based on detection of the magnetic characteristics of the ferromagnetic bodies.

1. A commodity inspection system which requires attaching metallic fibers to genuine commodities and judges whether inspection objects are genuine commodities based on detection of the magnetic characteristics of said metallic fibers, comprising:
a magnetic field applying means which applies upon an inspection object a magnetic field changing at a predetermined frequency;
a magnetic flux detecting means which detects a change of a magnetic flux density caused by a change of said magnetic field;
a frequency spectrum acquiring means which acquires a frequency spectrum corresponding to said change of said magnetic flux density; and
a judgment means which judges whether said inspection object is a genuine commodity based on said frequency spectrum acquired by said frequency spectrum acquiring means,
wherein said ferromagnetic bodies have a property of causing a steep magnetization reversal when applied with a magnetic field exceeding their coercive force,
said metallic fibers have a specific shape, and
said specific shape gives amplitude peak values to said frequency spectrum in accordance with said specific shape.

2. The commodity inspection system according to claim 1, wherein said specific shape is L-Shaped formed by bending said metallic fiber.

3. The commodity inspection system according to claim 1, wherein said specific shape is one or more notches formed on said metallic fiber.

4. The commodity inspection system according to claim 1, wherein said specific shape is one or more knots formed by knotting said metallic fiber.

5. The commodity inspection system according to any one of claims 1 through 4, wherein said inspection object is textile products and the weight of said metallic fiber attaching to said textile product is 30 mg or less.

6. A commodity inspection system which requires attaching multiple metallic fibers to genuine commodities and judges whether inspection objects are genuine commodities based on detection of the magnetic characteristics of said metallic fibers, comprising:
a magnetic field applying means which applies upon an inspection object a magnetic field changing at a predetermined frequency;
a magnetic flux detecting means which detects a change of a magnetic flux density caused by a change of said magnetic field;
a frequency spectrum acquiring means which acquires a frequency spectrum corresponding to said change of said magnetic flux density; and
a judgment means which judges whether said inspection object is a genuine commodity based on said frequency spectrum acquired by said frequency spectrum acquiring means,
wherein said ferromagnetic bodies have a property of causing a steep magnetization reversal when applied with a magnetic field exceeding their coercive force, and
said multiple metallic fibers are disposed to intersect each other so as to give amplitude peak values to said frequency spectrum.

7. The commodity inspection system according to claim 6, wherein said inspection object is a textile product and the weight of said multiple metallic fibers attached to said textile product is 30 mg or less.

8-11. (canceled)

12. Textile products mounting ferromagnetic bodies having a lower limit weight value which can be detected with a commodity inspection system detecting the magnetic characteristics of said ferromagnetic bodies supposed to be attached to said genuine commodities and accordingly judges whether an inspection object is a genuine commodity,
wherein, said commodity inspection system comprises:
a magnetic field applying means which applies upon an inspection object a magnetic field changing at a predetermined frequency;
a magnetic flux detecting means which detects a change of a magnetic flux density caused by a change of said magnetic field;
a frequency spectrum acquiring means which acquires a frequency spectrum corresponding to said change of said magnetic flux density; and
a judgment means which judges whether said inspection object is a genuine commodity based on said frequency spectrum acquired by said frequency spectrum acquiring means,
said ferromagnetic bodies cause a steep magnetization reversal when applied with a magnetic field exceeding their coercive force,
the upper limit weight value of said ferromagnetic bodies is a smaller value than the weight of a needle which can be detected with a needle inspection system detecting whether there is a needle inside a textile product, and
said upper limit weight value is 30 mg.

13-25. (canceled)
